(19) United States
(12) Patent Application Publication
(10) Pub. No.: US 2010/0233838 A1
(43) Pub. Date: Sep. 16, 2010

(54) Mounting of Solar Cells on a Flexible Substrate

(75) Inventor: Tansen Varghese, Albuquerque, NM (US)

Correspondence Address: EMCORE CORPORATION, 1600 EUBANK BLVD, S.E., ALBUQUERQUE, NM, 87123, US

(73) Assignee: Emcore Solar Power, Inc., Albuquerque, NM (US)

(21) Appl. No.: 12/401,137

(22) Filed: Mar. 10, 2009

(51) Int. Cl. H01L 21/50; H01L 21/20; H01L 21/304

(52) U.S. Cl. 438/64; 438/87; 438/68; 257/E21.09; 257/E21.237; 257/E21.499

(57) ABSTRACT

According to an embodiment, a method of manufacturing a solar cell includes depositing a sequence of layers of semiconductor material forming at least one solar cell on a first substrate; temporarily bonding a flexible film to a support second substrate; permanently bonding the sequence of layers of semiconductor material to the flexible film so that the flexible film is interposed between the first and second substrates; thinning the first substrate while bonded to the support substrate to expose the sequence of layers of semiconductor material; and subsequently removing the support substrate from the flexible film.

### FIELD OF THE INVENTION

The present application is directed to solar cell manufacturing and, more particularly, to mounting of solar cells on a flexible substrate.

### BACKGROUND

Thin solar cells are fabricated by depositing layers of light absorbing semiconductor material on the surface of a semiconductor wafer and then removing the wafer. The solar cell layer stack is typically bonded to a carrier to provide support during certain manufacturing steps, including removal of the semiconductor wafer. Additional processing can be performed after removal of the semiconductor wafer such as depositing metal wiring and cutting the thin layers of solar cell material into individual solar cell chips. Each solar cell chip can be removed from the support carrier and attached to a solar array device such as a solar panel, collector, etc. The solar cell chips can be made thin enough so that they flex when attached to curved surfaces.

The layers of solar cell material are typically attached to a carrier support using an adhesive or solder. It is difficult to remove the thin solar cell chips from the support carrier after the semiconductor wafer is removed and processing of the cells is completed. The thin solar cell chips are often damaged during the support substrate removal process, which can require excessively high temperatures and/or mechanical/chemical forces to break the bond formed between the solar cells and the support carrier. Damaging solar cells during the support substrate removal process significantly reduces conventional thin film solar cell manufacturing yields.

### SUMMARY

According to one embodiment, a method of manufacturing a solar cell includes depositing a sequence of layers of semiconductor material forming at least one solar cell on a first substrate; temporarily bonding a flexible film to a support second substrate; permanently bonding the sequence of layers of semiconductor material to the flexible film so that the flexible film is interposed between the first and second substrates; thinning the first substrate while bonded to the support substrate to expose the sequence of layers of semiconductor material; and subsequently removing the support substrate from the flexible film.

According to another embodiment, a method of manufacturing a solar cell includes depositing a sequence of layers of semiconductor material forming at least one solar cell on a first substrate; attaching a flexible film to a support second substrate with a temporary adhesive; attaching the sequence of layers of semiconductor material to the flexible film with a permanent adhesive so that the flexible film is interposed between the first and second substrates; thinning the first substrate while bonded to the support substrate to expose the sequence of layers of semiconductor material; and subsequently applying an adhesive remover to holes formed through the support substrate to dissolve the temporary adhesive and remove the support substrate from the flexible film.

According to yet another embodiment, a method of manufacturing a solar cell includes depositing a sequence of layers of semiconductor material forming at least one inverted metamorphic multifunction solar cell on a first substrate; temporarily bonding a flexible film to a support second substrate; permanently bonding the sequence of layers of semiconductor material to the flexible film so that the flexible film is interposed between the first and second substrates; thinning the first substrate while bonded to the support substrate to expose the sequence of layers of semiconductor material; and subsequently removing the support substrate from the flexible film.

Of course, the present invention is not limited to the above features and advantages. Those skilled in the art will recognize additional features and advantages upon reading the following detailed description, and upon viewing the accompanying drawings.

### BRIEF DESCRIPTION OF THE DRAWINGS

FIG. 1 illustrates an exploded perspective view of a solar cell structure temporarily attached to a support substrate according to an embodiment of the present invention.

FIGS. 2-6 illustrate cross-sectional views of the solar cell structure shown in FIG. 1 being temporarily attached to the support substrate according to an embodiment of the present invention.

FIGS. 7-9 illustrate cross-sectional views of the solar cell structure shown in FIG. 1 being processing after attachment to the support substrate according to an embodiment of the present invention.

FIG. 10 illustrates a side perspective view of individual solar cell chips manufactured according to an embodiment of the present invention attached to a surface.

### DETAILED DESCRIPTION

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

With this in mind, the present application is directed to permanently bonding a thin solar cell formed on a growth substrate to one side of a flexible film and temporarily bonding the other side of the flexible film to a support substrate so that the support substrate can be easily removed from the flexible film after processing of the thin solar cell is complete. Thin solar cells manufactured in accordance with the embodiments described herein weigh less and are thus well suited for applications where weight is a concern such as space applications. In addition, the solar cells are relatively thin and thus can be readily attached to curved surfaces. Still other advantages of having thin solar cells attached to a flexible film will become readily apparent in view of the detailed description below.

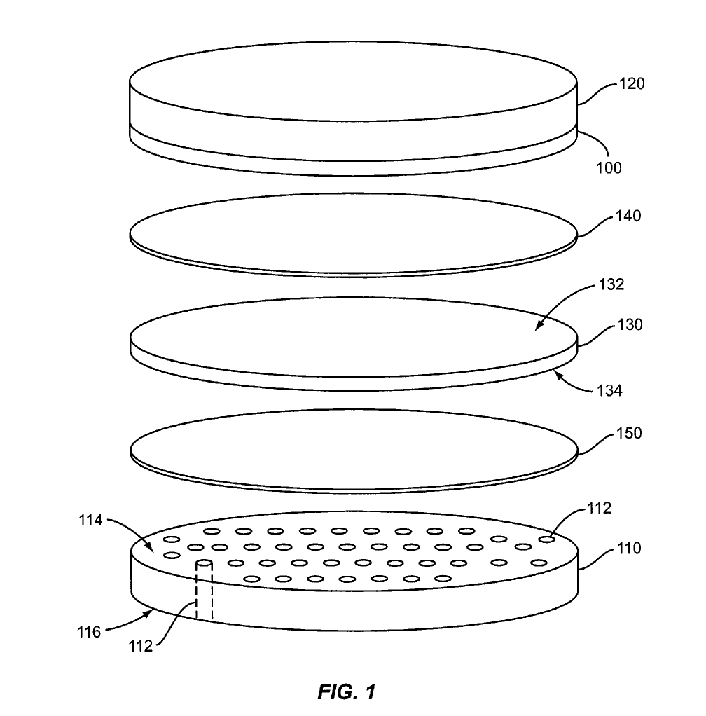

FIG. 1 shows an exploded perspective view of an embodiment of a sequence of layers of semiconductor material 100 temporarily bonded to a support substrate 110. The sequence of layers of semiconductor material 100 forms at least one solar cell and is deposited on a growth substrate 120 such as a GaAs wafer, Ge wafer, etc. A flexible film 130 is interposed between the support substrate 110 and the growth substrate 120. In one embodiment, the flexible film 130 is a polyimide film such as Kapton (manufactured by DuPont.). One side 132 of the flexible film 130 is permanently bonded to the sequence of layers of semiconductor material 100 using a permanent adhesive 140 so that the flexible film 130 cannot be easily removed from the sequence of layers of semiconductor material 100. The other side 134 of the flexible film 130 is temporarily bonded to the support substrate 110 using a temporary adhesive 150 so that the support substrate 110 can be easily removed from the flexible film 130 without causing damage to the sequence of layers of semiconductor material 100.

The support substrate 110 provides support to the sequence of layers of semiconductor material 100 during subsequent processing step(s). This way, the growth substrate 120 on which the sequence of layers of semiconductor material 100 is deposited can be removed after attachment to the support substrate 110. The sequence of layers of semiconductor material 100 can also be segmented into individual solar cell chips (not shown in FIG. 1) when attached to the support substrate 110 without causing damage to the chips. After completing the desired processing step(s), the support substrate 110 is removed from the flexible film 130. In one embodiment, the support substrate 110 has holes 112 which extend from one surface 114 of the support substrate 110 to the opposing surface 116 as indicated by the dashed lines in the Figures. The support substrate 110 may comprise any suitable material such as sapphire or any other material having suitable chemical and temperature stability and strength. In one embodiment, the support substrate 110 is removed from the flexible film 130 by applying an adhesive remover to the holes 112 which dissolves the temporary adhesive 150, leaving the sequence of layers of semiconductor material 100 permanently bonded to the flexible film 130.

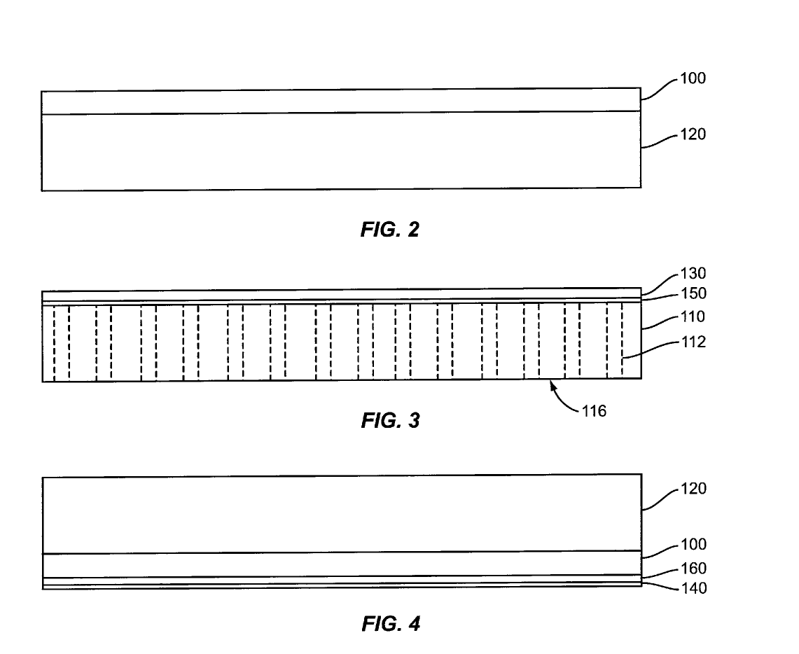

FIG. 2 shows a cross-sectional view of the growth substrate 120 after the sequence of layers of semiconductor material 100 is deposited on the substrate 120, e.g. via epitaxial growth. The sequence of layers of semiconductor material 100 can include any number and type of layers of semiconductor material for generating current in response to incident light. In one embodiment, the layers 100 form at least one inverted metamorphic multifunction (IMM) solar cell, e.g., as described in co-pending U.S. patent application Ser. No. 12/271,192 filed Nov. 14, 2008, the contents of which is incorporated herein by reference in its entirety.

According to one embodiment, the sequence of layers of semiconductor material 100 is deposited on the growth substrate 120 by forming a first solar subcell on the growth substrate 110 having a first band gap and forming a second solar subcell over the first solar subcell having a second band gap smaller than the first band gap. A grading interlayer is formed over the second solar subcell having a third band gap larger than the second band gap. A third solar subcell having a fourth band gap smaller than the second band gap is formed such that the third solar subcell is lattice mismatched with respect to the second solar subcell. In one embodiment, the first solar subcell is composed of an InGaAlP emitter region and an InGaAlP base region and the second solar subcell is composed of an InGaP emitter region and an InGaAs base region. The grading interlayer can be composed of InGaAlAs. Alternatively, the grading interlayer can be composed of a plurality of layers with a monotonically increasing lattice constant. Yet other layers of semiconductor material can be deposited on the growth substrate 120 to form a solar cells which is now ready for attachment to the support substrate 110.

FIG. 3 shows a cross-sectional view of the support substrate 110 during bonding to the flexible film 130. The support substrate 110 is bonded to the flexible film 130 using a temporary adhesive 150 such as Wafer Bond (manufactured by Brewer Science, Inc. of Rolla, Mo.) or any other type of suitable polymer that can be applied by spin coating and has suitable chemical and temperature stability and relatively low curing temperature to produce a temporary bond which can be easily broken without causing damage to the sequence of layers of semiconductor material 100 temporarily attached to the support substrate 110.

In one embodiment, the flexible film 130 is vacuum sealed to a chuck (not shown) and the temporary adhesive 150 spun onto the film 130. The support substrate 110 is then mated with the flexible film 130 while on the chuck. Alternatively, the temporary adhesive 150 can be spun onto the support substrate 110. According to this embodiment, the holes 112 formed in the support substrate 110 are temporarily plugged so that the adhesive 150 does not escape through the holes 112. The holes 112 can be plugged by placing tape (not shown) over the side 116 of the support substrate 110 not being bonded to the flexible film 130. The tape can be removed after the support substrate 110 and flexible film 130 are brought into contact. The support substrate 110 and the flexible film 130 are then bonded together via the temporary adhesive 150 under appropriate heat and/or pressure conditions for curing the temporary adhesive 150. The growth substrate 120 with the sequence of layers of semiconductor material 100 is also prepared for bonding to the flexible film 130.

FIG. 4 shows a cross-sectional view of the growth substrate 120 after the sequence of layers of semiconductor material 100 is deposited thereon. According to one embodiment, the sequence of layers of semiconductor material 100 has a metallized surface 160. Alternatively, the sequence of layers of semiconductor material 100 does not have a metallized surface. In either case, a permanent adhesive 140 such as benzocyclobutene (BCB) or SU-8 is applied to the surface of the sequence of layers of semiconductor material 100 facing away from the growth substrate 120. The permanent adhesive 140 can also be applied to the surface 132 of the flexible film 130 not bonded to the support substrate 120 for increased adhesion.

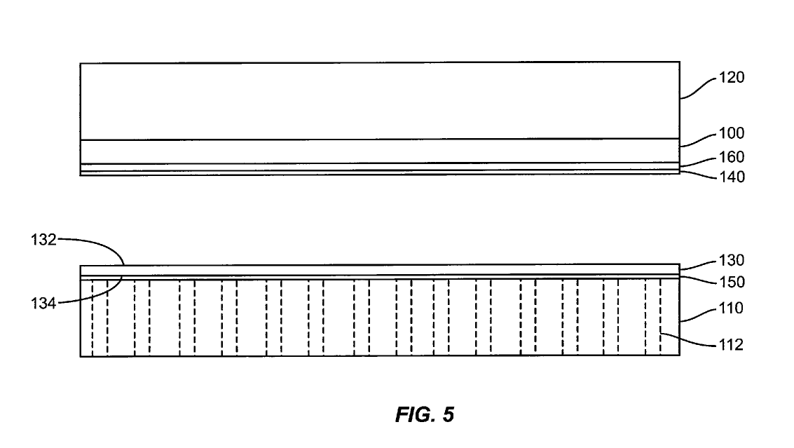

FIG. 5 shows a cross-sectional view of the two substrates 110, 120 during the substrate attachment process. The substrates 110, 120 are brought into contact so that the sequence of layers of semiconductor material 100 can be permanently bonded to one surface 132 of the flexible film 130 via the permanent adhesive 140 and the support substrate 110 can be temporarily bonded to the other surface 134 of the flexible film 130 via the temporary adhesive 150. In one embodiment, the substrates 110, 120 are brought into contact under vacuum to prevent air voids in the adhesives 140, 150. An appropriate temperature and/or pressure are applied to the substrates 110, 120 for curing the permanent adhesive 140. Alternatively, the flexible film 130 can be permanently bonded to the sequence of layers of semiconductor material 100 and then temporarily bonded to the support substrate 110. In either case, the support substrate 110 is temporarily bonded to the sequence of layers of semiconductor material 100.

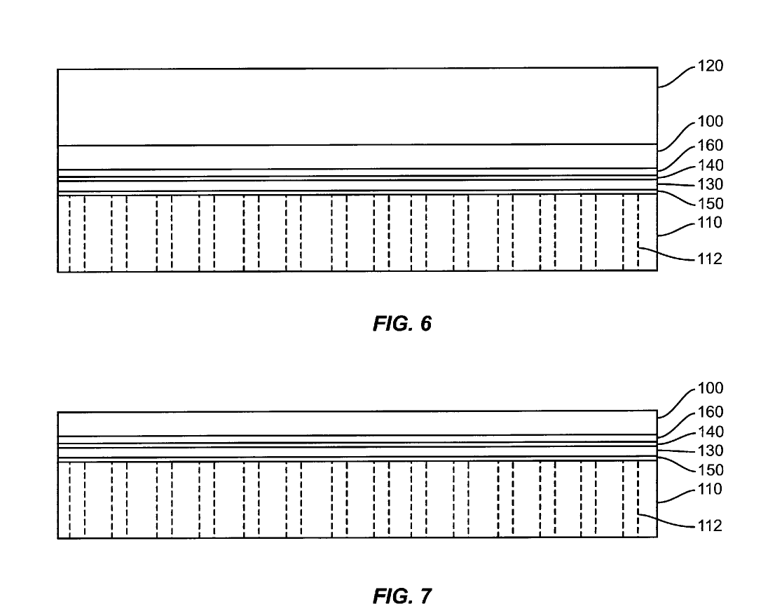

FIG. 6 shows a cross-sectional view of the two substrates 110, 120 after the substrates 110, 120 are bonded together. At this point, the support substrate 110 can be used to support the sequence of layers of semiconductor material 100 during subsequent processing step(s).

FIG. 7 shows a cross-sectional view of the bonded structure after the growth substrate 120 is removed, leaving only the sequence of layers of semiconductor material 100 and the flexible film 130 bonded to the support substrate 110. The growth substrate 120 can be removed by grinding, lapping and/or etching. The support substrate 110 prevents the thin sequence of layers of semiconductor material 100 from being damaged during the substrate removal process. Additional processing can be done to the sequence of layers of semiconductor material 100 while temporarily attached to the support substrate 110.

FIG. 8 is a cross-sectional view of the bonded structure after the growth substrate 120 is removed and after a metal grid 200 is formed on the exposed surface of the sequence of layers of semiconductor material 100. The metal grid 200 collects current from across the surface of the cell, and also can be contacted to bring current to the outside world, interconnect adjacent cells, etc. In one embodiment, the metal grid 200 is formed by evaporation and lithographic patterning.

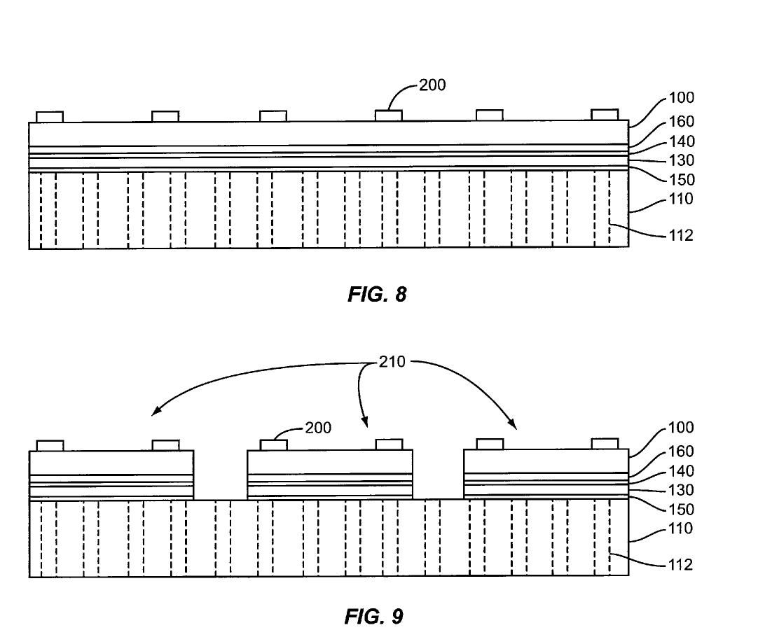

FIG. 9 is a cross-sectional view of the bonded structure after the sequence of layers of semiconductor material 100 is cut into a plurality of thin solar cell chips 210. The flexible film 130 interposed between the layers of semiconductor material 100 and the support substrate 110 can also be cut so that each solar cell chip 210 can be easily separated from the support substrate 110 and still have a portion of the flexible film 130 permanently attached thereto. In one embodiment, the solar cell chips 210 are removed from the support substrate 110 by applying an adhesive remover to the holes 112 formed through the support substrate 110. The adhesive remover travels through the holes 112 and dissolves the temporary adhesive 150, freeing the solar cell chips 210 and the flexible film 130 from the support substrate 110 without damaging the chips 210.

In another embodiment, the support substrate 110 does not have holes 112 formed therein and the temporary adhesive 150 is dissolved by heating the adhesive 150 to a temperature which breaks the temporary bond between the support substrate 110 and the flexible film 130. The individual solar cell chips 210 each with a layer of the flexible film 130 permanently bonded thereto can then be attached to any type of desirable surface. The solar cell chips 210 are thin and flexible and can be readily attached to flat or curved surfaces. Cover glasses (not shown) and interconnects 200 can be applied to solar cell chips 210 either before or after demounting from the support substrate 110 since the flexible film 130 provides ample support to the chips 210 during this type of processing. The flexible film 130 permanently bonded to the solar cell chips 210 can be sucked down with a vacuum to make the film 130 flat to do cover glassing and welding or soldering.

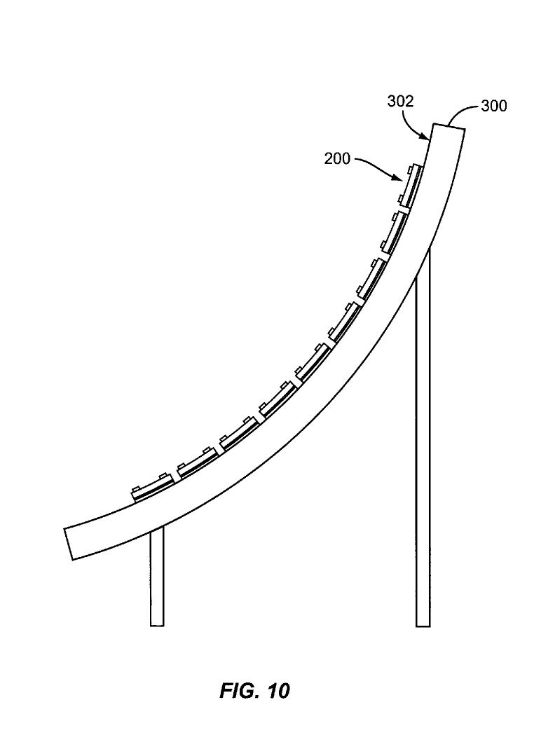

FIG. 10 shows a side-view of an embodiment of a solar panel 300 having a curved surface 302 to which the solar cell chips 210 can be attached. The solar cell chips 210 can be permanently or temporarily attached to the solar panel 300, e.g. via an appropriate type of adhesive.

Spatially relative terms such as “under”, “below”, “lower”, “over”, “upper”, and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The present invention may be carried out in other specific ways than those herein set forth without departing from the scope and essential characteristics of the invention. The present embodiments are, therefore, to be considered in all respects as illustrative and not restrictive, and all changes coming within the meaning and equivalency range of the appended claims are intended to be embraced therein.

What is claimed is:

1. A method of manufacturing a solar cell, comprising:
depositing a sequence of layers of semiconductor material forming at least one solar cell on a first substrate;
temporarily bonding a flexible film to a support second substrate;
permanently bonding the sequence of layers of semiconductor material to the flexible film so that the flexible film is interposed between the first and second substrates;
thinning the first substrate while bonded to the support substrate to expose the sequence of layers of semiconductor material; and
subsequently removing the support substrate from the flexible film.

2. The method of claim 1, wherein temporarily bonding the flexible film to the support substrate comprises:
applying a temporary adhesive to a surface of the flexible film or the support substrate; and
bonding the flexible film to the support substrate with the temporary adhesive.

3. The method of claim 2, wherein subsequently removing the support substrate from the flexible film comprises applying an adhesive remover to holes formed through the support substrate to dissolve the temporary adhesive.

4. The method of claim 2, wherein the temporary adhesive comprises a spin on polymer.

5. The method of claim 1, wherein permanently bonding the sequence of layers of semiconductor material to the flexible film comprises:
applying a permanent adhesive to a surface of the flexible film or a metallized surface of the sequence of layers of semiconductor material; and
bonding the flexible film to the sequence of layers of semiconductor material with the permanent adhesive.

6. The method of claim 1, further comprising separating the sequence of layers of semiconductor material and the flexible film into individual solar cell chips while the sequence of layers of semiconductor material are still bonded to the support substrate.

7. The method of claim 1, further comprising attaching the surface of the flexible film removed from the support substrate to a surface.

8. The method of claim 1, wherein the first substrate is composed of GaAs.

9. The method of claim 1, wherein depositing a sequence of layers of semiconductor material forming at least one solar cell on the first substrate includes:
forming a first solar subcell on the first substrate having a first band gap;
forming a second solar subcell over the first solar subcell having a second band gap smaller than the first band gap;
forming a grading interlayer over the second solar subcell having a third band gap larger than the second band gap;
forming a third solar subcell having a fourth band gap smaller than the second band gap such that the third solar subcell is lattice mismatched with respect to the second solar subcell.

10. The method of claim 9, wherein the first solar subcell is composed of an InGaAlP emitter region and an InGaAlP base region.

11. The method of claim 9, wherein the second solar subcell is composed of an InGaP emitter region and an InGaAs base region.

12. The method of claim 9, wherein the grading interlayer is composed of InGaAlAs.

13. The method of claim 9, wherein the grading interlayer is composed of a plurality of layers with a monotonically increasing lattice constant.

14. A method of manufacturing a solar cell, comprising:
depositing a sequence of layers of semiconductor material forming at least one solar cell on a first substrate;
attaching a flexible film to a support second substrate with a temporary adhesive;
attaching the sequence of layers of semiconductor material to the flexible film with a permanent adhesive so that the flexible film is interposed between the first and second substrates;
thinning the first substrate while bonded to the support substrate to expose the sequence of layers of semiconductor material; and
subsequently applying an adhesive remover to holes formed through the support substrate to dissolve the temporary adhesive and remove the support substrate from the flexible film.

15. The method of claim 14, wherein the flexible film comprises a polyimide film.

16. The method of claim 14, wherein attaching the flexible film to the support substrate with a temporary adhesive comprises:
plugging the holes formed through the support substrate;
spinning the temporary adhesive onto the flexible film or the support substrate while the holes are plugged; and
curing the temporary adhesive.

17. The method of claim 16, further comprising separating the sequence of layers of semiconductor material and the flexible film into individual solar cell chips before the support substrate is removed from the flexible film.

18. A method of manufacturing a solar cell, comprising:
depositing a sequence of layers of semiconductor material forming at least one inverted metamorphic multifunction solar cell on a first substrate;
temporarily bonding a flexible film to a support second substrate;
permanently bonding the sequence of layers of semiconductor material to the flexible film so that the flexible film is interposed between the first and second substrates;
thinning the first substrate while bonded to the support substrate to expose the sequence of layers of semiconductor material; and
subsequently removing the support substrate from the flexible film.

19. The method of claim 18, wherein permanently bonding the sequence of layers of semiconductor material to the flexible film comprises permanently bonding a metallized surface of the sequence of layers of semiconductor material to the flexible film with a permanent adhesive.

20. The method of claim 19, wherein subsequently removing the support substrate from the flexible film comprises applying an adhesive remover to holes formed through the support substrate to dissolve the temporary adhesive and remove the support substrate from the flexible film.
